(19) United States
(12) Patent Application Publication
(10) Pub. No.: US 2012/0119209 A1
(43) Pub. Date: May 17, 2012

(54) SEMICONDUCTOR DEVICES AND METHOD OF MANUFACTURING THE SAME

(75) Inventor: Young Bok LEE, Icheon-si (KR)

(73) Assignee: HYNIX SEMICONDUCTOR INC., Icheon-si (KR)

(21) Appl. No.: 13/297,712

(22) Filed: Nov. 16, 2011

(30) Foreign Application Priority Data
Nov. 17, 2010 (KR) 10-2010-0114397

(51) Int. Cl. H01L 23/48; H01L 21/28

(52) U.S. Cl. 257/48; 438/586; 257/E23.01; 257/E21.158

(57) ABSTRACT

A semiconductor device includes isolation layers arranged in a memory array region and a monitoring region, wherein the isolation layers are positioned in parallel; gate lines arranged to cross the isolation layers in the memory array region, wherein the gate lines are formed in the memory array region; dummy gate lines arranged in a substantially same direction as the isolation layers in the monitoring region, wherein the dummy gate lines are formed in the monitoring region; monitoring junctions arranged between the dummy gate lines and in a substantially same direction as the dummy gate lines, wherein the monitoring junctions are arranged in the monitoring region; and spacers arranged on sidewalls of each of the gate lines and the dummy gate lines, wherein at least one of the monitoring junctions is covered by any one of the spacers.

### CROSS-REFERENCE TO RELATED APPLICATION

This application claims priority to Korean patent application number 10-2010-0114397 filed on Nov. 17, 2010, in the Korean Intellectual Property Office, the entire disclosure of which is incorporated by reference herein.

### BACKGROUND

1. Field of the Invention

Example embodiments relate to semiconductor devices and a method of manufacturing the same and, more particularly, to semiconductor devices and a method of manufacturing the same, which are capable of improving the accuracy of analysis into junctions formed in a memory array region.

2. Description of the Related Art

In order abate leakage current characteristic of memory cells forming a semiconductor device, shallow junctions are introduced. In order to check the electrical characteristics of the shallow junctions, junction test patterns are formed in a monitoring region of the semiconductor device. The semiconductor device may comprise a monitoring region that is separated from a memory array region where memory cells are formed. The junction test patterns for monitoring characteristics of the semiconductor device are also formed in the monitoring region. The test patterns are formed using the same process as the memory cells formed in the memory array region. The monitoring junctions of the test patterns are formed using the same process as the junctions of the memory array region, and monitoring junctions are used to analyze the junction characteristics of the memory array region.

FIG. 1 is a prior art diagram showing part of a memory array region and a monitoring region of a known semiconductor device.

Referring to FIG. 1, usually with a NAND flash memory device, the memory array region includes first isolation regions 3a where trenches and isolation layers are formed, and first active regions 1a that may be partitioned by the first isolation regions 3a. The first active regions 1a are part of a semiconductor substrate and parallel to each other. The first active regions 1a are defined between isolation layers which are formed over the first isolation regions 3a and spaced from one another.

Furthermore, gate lines such as, drain select lines DSL, source select lines SSL, and word lines WL are formed such that the lines cross over the first isolation regions 3a and the first active regions 1a. The gate lines include first gate lines, including drain select lines DSL and source select lines SSL, and second gate lines including a plurality of word lines WL formed between adjacent the drain select line DSL and the source select line SSL. Impurities are implanted into the first active regions la between the gate lines DSL, SSL, and WL, thereby forming junctions. The junctions formed between the drain select lines DSL become drains, and drain contact plugs DCT are formed over the drains. The junctions formed between the source select lines SSL become sources, and source contact lines SCT are formed over the sources. The junctions formed between the word lines WL become cell junctions.

The monitoring region includes second isolation regions 3b, in which trenches and isolation layers are formed, and second and third active regions 1b and 1c. The second active regions 1b are spaced and parallel, and the third active regions 1c are coupled to both ends of the second active region 1b. The second active regions 1b and the third active regions 1c are defined by isolation layers formed in the second isolation regions 3b and these regions 1b, 1c are part of a semiconductor substrate.

Just as with the junctions of the memory array region, impurities are implanted into the second and the third active regions 1b and 1c. At least one of the second active regions 1b coupled between the third active regions 1c may be used as monitoring junctions for checking the characteristics of the junctions of the memory array region.

Metal pads 5 are formed over the third active regions 1c. The metal pad 5 is electrically coupled with the third active region 1c via a contact plug CT. Accordingly, characteristics of a monitoring junction formed in the second active region 1b can be analyzed through the metal pad 5. The characteristics of junctions formed in the first active region 1a, however, are not incorporated into the second active region 1b because the second active regions 1b are lost in a fabrication process. What it means to be lost during a fabrication process is explained below. A method of manufacturing the known semiconductor device is described below.

FIGS. 2A and 2B are cross-sectional views illustrating a method of manufacturing the semiconductor device depicted in FIG. 1. In particular, FIG. 2A is a cross-sectional view taken along line A-A of the memory array and of FIG. 1, and FIG. 2B is a cross-sectional view taken along line B-B of the monitoring region.

Referring to FIGS. 1 and 2A, trenches and isolation layers for partitioning the first to third active regions 1a, 1b and 1c of the semiconductor substrate 1 are formed in the first and the second isolation regions 3a and 3b of the semiconductor substrate 1.

The trenches may be formed by first stacking a gate insulation layer 11 and a first conductive layer 13 over the semiconductor substrate 1, and forming isolation mask patterns (not shown) on the first conductive layer 13. The first conductive layer 13, the gate insulation layer 11, and the semiconductor substrate 1 that are exposed between the isolation mask patterns may then be etched. Areas not covered by the isolation mask pattern may be etched away to form the trenches.

After the trenches are formed, the isolation layers may be formed by filling the trenches with an insulating substance. Next, the isolation mask patterns are removed. In the process of forming the trenches and the isolation layers, portions of the gate insulation layer 11 and the first conductive layer 13 are removed to expose the first and the second isolation regions 3a and 3b, but other portions of these layers 11, 13 remain on the first to third active regions 1a, 1b, and 1c.

Next, a dielectric layer 15, a second conductive layer 17, and a gate hard mask pattern 19 are stacked. Before the second conductive layer 17 is formed, a contact hole is formed through the dielectric layer 15 to provide access to the first conductive layer 13. The contact hole may accommodate the source select line SSL and the drain select line DSL.

Next, the second conductive layer 17, the dielectric layer 15, and the first conductive layer 13 exposed between the gate hard mask patterns 19 are etched by an etch process using the gate hard mask patterns 19 as an etch mask. Here, the gate insulation layer 11 may also be etched. Consequently, the isolation layers, and the drain select lines DSL, the word lines WL, and the source select lines SSL spaced from one another are formed in the memory array region of the semiconductor substrate 1. The drain select lines DSL, the word lines WL, and the source select lines SSL are spaced from one another and formed to cross the first active regions 1a.

Furthermore, in the memory array region of the semiconductor substrate 1, the first active regions 1a between the isolation layers are exposed between the drain select lines DSL, the word lines WL, and the source select lines SSL. On the other hand, in the monitoring region of the semiconductor substrate 1, the second and the third active regions 1b and 1c are generally exposed. The drain contact plugs DCT should be subsequently formed between the drain select lines DSL, and the source contact lines SCT should be subsequently formed between the source select lines SSL. Accordingly, a space between the drain select lines DSL and a space between the source select lines SSL are wider than a space between the word lines WL.

Next, impurities are implanted into the first active regions 1a and the second and the third active regions 1b and 1c which are exposed. Consequently, a drain junction 7D is formed between the drain select lines DSL, a source junction (not shown) is formed between the source select lines SSL, cell junctions may be formed between drain select lines DSL and word lines WL, between the source select lines SSL and word lines WL, and between the word lines WL. The only cell junction 7C depicted in FIG. 2a falls between two word lines WL. A monitoring junction 7M is also formed between the third active regions 1c.

Referring to FIGS. 1 and 2B, spacers 21 are formed on the sidewalls of the gate insulation layer 11, the first conductive layer 13, the dielectric layer 15, and the second conductive layer 17. A space between the word lines WL having a relatively narrow width may be completely filled with the spacers 21. A space having a relatively wide width between the drain select lines DSL and a space having a relatively wide width between the source select lines SSL are not completely filled with the spacers 21. Because the space between the drain select lines DSL and the source select lines SSL are not completely filled with the spacers 21, the drain junctions 7D and the source junctions may be exposed between the spacers 21.

The spacers 21 may be formed by forming a spacer layer over the semiconductor substrate 1 where the drain select lines DSL, the word lines WL, and the source select lines SSL are formed and etching the spacer layer using an etch process, such as etch-back, so that the drain junctions 7D and the source junctions are exposed. The area of the etched spacer layer is wider in the monitoring region than between the drain select lines DSL or between the source select lines SSL.

Accordingly, the monitoring junctions 7M are formed in the second active regions 1b of the monitoring region before the drain junctions 7D and the source junctions are exposed. Because the monitoring junctions 7M are first exposed, the monitoring junctions 7M thus may be lost under the influence of the etch process of the spacer layer. The depth D1 of the junctions 7D and 7C of the memory array region becomes different from the depth D2 of the monitoring junction 7M of the monitoring region, so that the electrical characteristics of the junctions 7D and 7C of the memory array region are not precisely incorporated into the monitoring junctions 7M.

In particular, if the junctions 7D and 7C of the memory array region have shallow junctions in order to improve the leakage current characteristic of the semiconductor device, characteristics of memory cells cannot be precisely monitored because the monitoring junction 7M is broken owing to a loss of the monitoring junction 7M.

### BRIEF SUMMARY

Example embodiments relate to semiconductor devices and a method of manufacturing the same, which can improve the accuracy of analysis into junctions formed in the memory array region a semiconductor device.

A semiconductor device according to an aspect of the present disclosure includes isolation layers arranged in a memory array region and a monitoring region, wherein the isolation layers are positioned in parallel; gate lines arranged to cross the isolation layers in the memory array region, wherein the gate lines are formed; dummy gate lines arranged in a substantially same direction as the isolation layers in the monitoring region, wherein the dummy gate lines are formed in the monitoring region; monitoring junctions arranged between the dummy gate lines and in a substantially same direction as the dummy gate lines, wherein the monitoring junctions are formed in the monitoring region; and spacers arranged on sidewalls of each of the gate lines and the dummy gate lines, wherein at least one of the monitoring junctions is covered by any one of the spacers.

A method of manufacturing a semiconductor device according to another aspect of the present disclosure includes forming isolation layers, in a memory array region and a monitoring region, wherein the isolation layers are positioned in parallel; forming gate lines crossing the isolation layers in the memory array region and dummy gate lines arranged in a direction of the isolation layers in the monitoring region;

forming monitoring junctions arranged between the dummy gate lines and in a substantially same direction as the dummy gate lines; and forming spacers on sidewalls of each of the gate lines and the dummy gate lines, wherein at least one of the monitoring junctions is covered by any one of the spacers.

### BRIEF DESCRIPTION OF THE DRAWINGS

FIG. 1 is a diagram showing part of a memory array region and a monitoring region of a prior art semiconductor device;

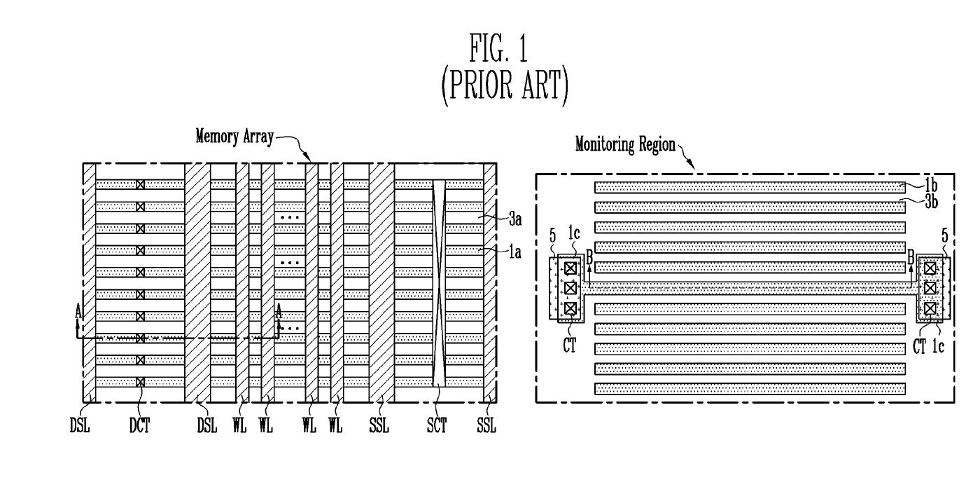

FIGS. 2A and 2B are cross-sectional views illustrating a method of manufacturing the prior art semiconductor device;

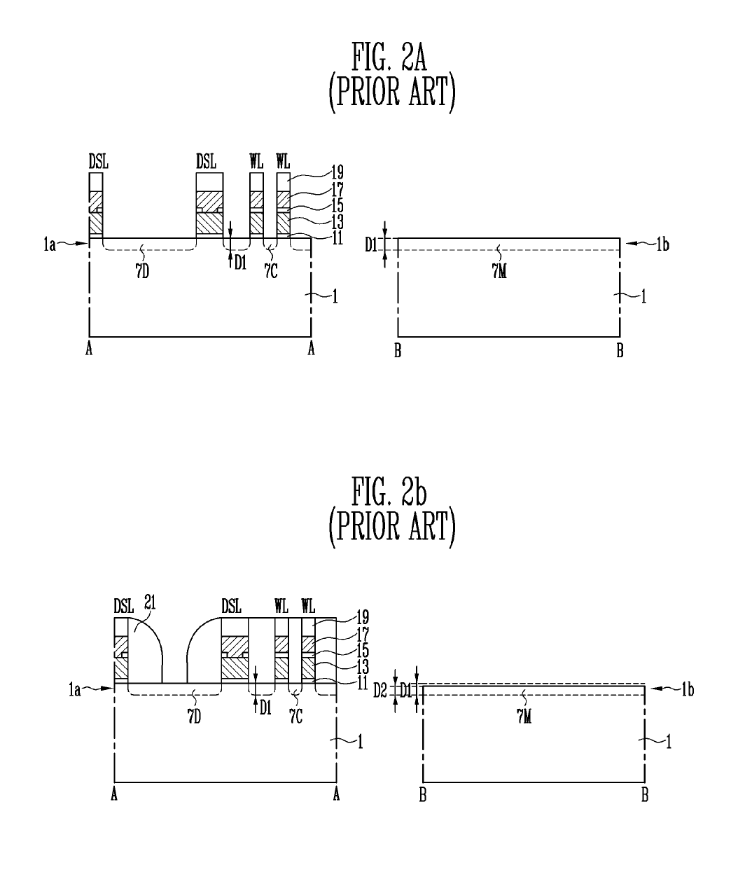

FIG. 3 is a diagram showing part of the memory array region of a semiconductor device and a monitoring region according to an embodiment of this disclosure; and

FIGS. 4A to 4C are cross-sectional views illustrating a method of manufacturing the semiconductor device according to an embodiment of this disclosure.

### DESCRIPTION OF EMBODIMENTS

Hereinafter, some example embodiments of the present disclosure will be described in detail with reference to the accompanying drawings. Figures are provided to allow those having ordinary skill in the art to understand the scope of the embodiments of the disclosure.

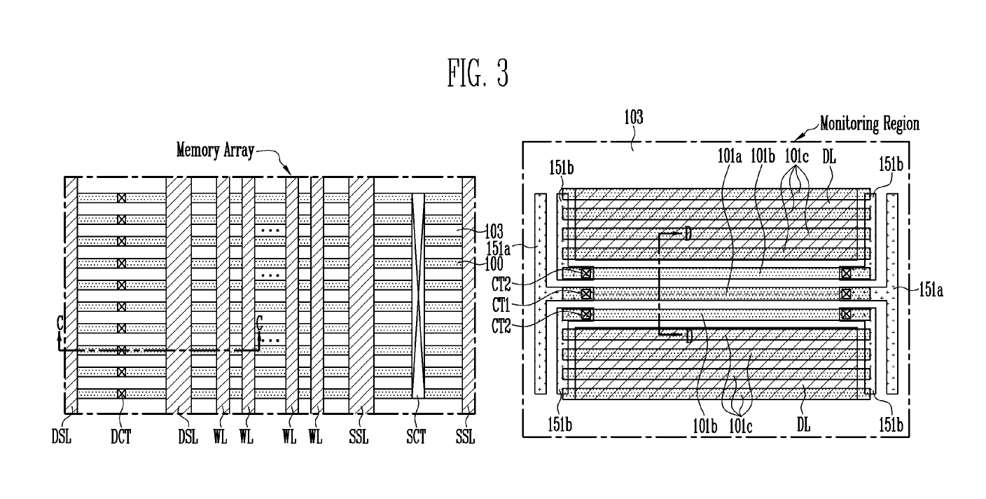

FIG. 3 is a diagram showing part of a memory array region and monitoring region of a semiconductor device according to an embodiment of this disclosure.

Referring to FIG. 3, a NAND flash memory device may comprise a memory array region including first active regions 100 partitioned by isolation layers 103. The isolation layers 103 may be formed in parallel a semiconductor substrate and there may be spacing between the isolation layers 103. The first active regions 100 are part of the semiconductor substrate and formed in parallel with the isolation layer 103 that may be interposed between first active regions 100.

Gate lines DSL, SSL, and WL are formed in the memory array region of the semiconductor substrate so that the gate lines cross the first active regions 100 and the isolation layers 103 in a substantially perpendicular manner. The gate lines may comprise first gate lines, including drain select lines DSL and source select lines SSL. The gate lines may also comprise second gate lines including a plurality of word lines WL disposed between the drain select line DSL and the source select line SSL.

Junctions are formed in the first active region 100 between the isolation layers 103 of the memory array region and are arranged between adjacent the gate lines DSL, SSL, and WL. The junctions are separated from each other by the first gate line DSL and SSL and the second gate line WL interposed between DSL and SSL. The junctions include first, and second junctions. First junctions may be formed between the first gate lines DSL or SSL. Second junctions may be formed between the first gate line DSL or SSL and the second gate line WL. Second junctions may also be formed between the second gate lines WL. The first junction formed between the drain select lines DSL, from among the first junctions, is a drain junction. The first junction formed between the source select lines SSL, from among the first junctions, is a source junction. Drain contact plugs DCT are coupled to the drain junctions, and source contact lines SCT are coupled to the source junctions. Furthermore, the second junction formed between the second gate lines WL is a cell junction.

The monitoring region includes a second active region 101a, a third active region 101b, and a fourth active region 101c. The second to fourth active regions 101a-c may be partitioned by the isolation layers 103. The second to fourth active regions 101a-c are spaced from one another in parallel, and the isolation layers 103 are spaced from one another in parallel. The third active regions 101b are disposed on both side of the second active region 101a, and the fourth active regions 101c are disposed on both sides of the second active region 101a with the third active regions 101b interposed therebetween.

The second to fourth active regions 101a-c are part of the semiconductor substrate and partitioned by the isolation layers 103 of the monitoring region. Dummy gate lines DL are formed over the fourth active regions 101c in a substantially same direction as the fourth active regions 101c and the isolation layers 103. The second and the third active regions 101a and 101b are exposed between the dummy gate lines DL.

The same impurities as the impurities implanted into the junctions of the memory array region are implanted into the second and the third active regions 101a and 101b, thus forming monitoring junctions in a substantially same direction as the dummy gate lines DL. Consequently, the second and the third active regions 101a and 101b may be used as junction test patterns for analyzing characteristics of the junctions of the memory array region.

Meanwhile, the second active region 101a is exposed between spacers formed on sidewalls of the dummy gate lines DL, and the third active regions 101b is covered by any one of the spacers formed on the sidewalls of the dummy gate lines DL. Accordingly, a first monitoring junction formed in the second active region 101a may be used to analyze characteristics of the first junction between the first gate lines DSL or SSL which is exposed between the spacers when the spacers are formed. Furthermore, a second monitoring junction formed in the third active region 101b may be used to analyze characteristics of the second junction between the second gate lines WL which is covered by any one of the spacers when the spacers are formed.

First contact plugs CT1 coupled to the first monitoring junction are formed over both ends of the first monitoring junction of the second active region 101a. First metal pads 151a coupled to the first contact plugs CT1 are formed over the first contact plugs CT1. Each of the first metal pads 151a is electrically coupled to the first monitoring junction via the first contact plug CT1.

Second contact plugs CT2 coupled to the second monitoring junctions are formed over both ends of second monitoring junction of the third active region 101b. Second metal pads 151b coupled to the second contact plugs CT2 are formed over the second contact plugs CT2, respectively. Each of the second metal pads 151b is electrically coupled the second monitoring junction via the second contact plug CT2.

A method of manufacturing the semiconductor device according to an embodiment of this disclosure is described below.

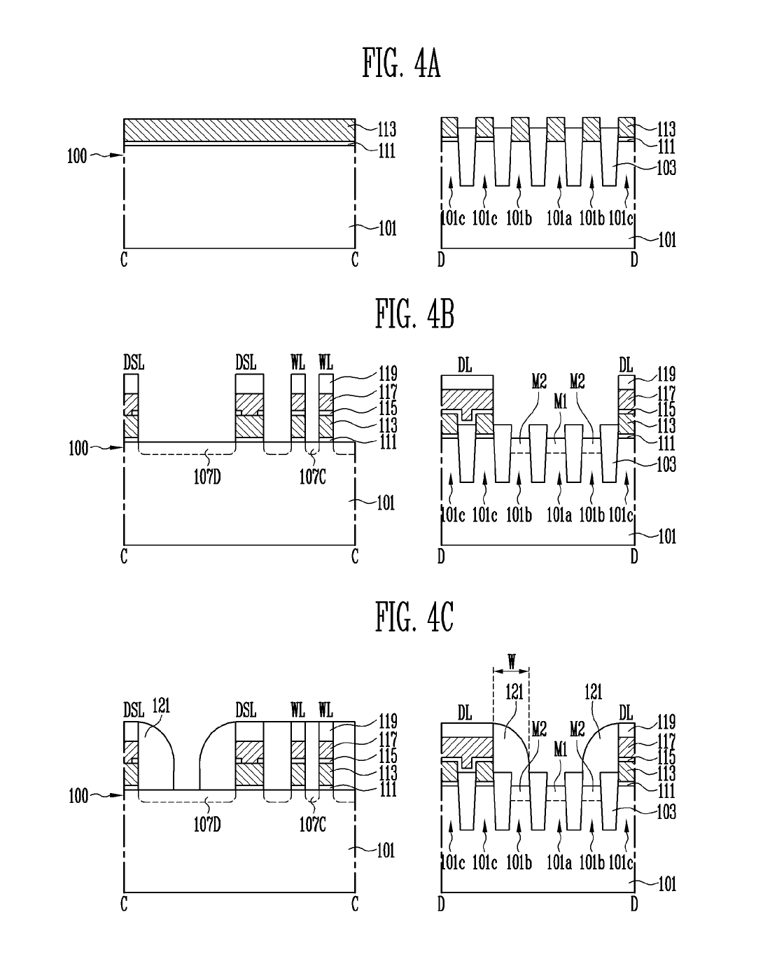

FIGS. 4A to 4C are cross-sectional views illustrating the method of manufacturing the semiconductor device according to an embodiment of this disclosure. In particular, FIGS. 4A to 4C are cross-sectional views taken along line C-C and D-D of FIG. 3.

Referring to FIGS. 3 and 4A, the isolation layers 103 spaced from one another are formed in the memory array region and the monitoring region of the semiconductor substrate 101. Consequently, the first active regions 100 are defined in parallel in the memory array region and are spaced from one another by the isolation layers 103. The second, third and fourth active regions 101a, 101b, and 101c are defined in parallel in the monitoring region and are spaced from one another by the isolation layers 103.

The isolation layers 103 may be formed by forming trenches in the semiconductor substrate 101, filling the trenches with an insulating substance, and then controlling the height of the insulating substance by using an etch process on the insulating substance. The trenches may be formed by first stacking a gate insulation layer 111 and a first conductive layer 113 over the semiconductor substrate 101, and forming isolation mask patterns (not shown) on the first conductive layer 113. The first conductive layer 113, the gate insulation layer 111, and the semiconductor substrate 101 that are exposed between the isolation mask patterns may be etched. Areas not covered by the isolation mask pattern may be etched away to form the trenches.

Consequently, the gate insulation layer 111 and the first conductive layer 113 remain over the first to fourth active regions 100, 101a and 101b, and 101c, but are removed from the isolation regions. The gate insulation layer 111 may be used as a tunnel dielectric layer in the memory array region of the NAND flash memory device. And the first conductive layer 113 may be used as a conductive layer for floating gates in the memory array region of the NAND flash memory device.

After the isolation layers 103 are formed, the isolation mask patterns are removed.

In order to increase monitoring accuracy in each of the first active regions 100 the width of each of the second to fourth active regions 101a and 101b, and 101c may be identical or substantially the same as the width of the first active region 100. The width of the isolation layer 103 between the second and the third active regions 101a and 101b and the width of the isolation layer 103 between the third and the fourth active regions may be or substantially the same as the width of the isolation layer 103 between the first active regions 100.

Referring to FIGS. 3 and 4B. FIG. 4B depicts the semiconductor device after the isolation mask is removed, leaving a dielectric layer 115 and a second conductive layer 117 stacked on the first conductive layer 113. Gate hard mask patterns 119 are formed on the second conductive layer 117. The second conductive layer 117, the dielectric layer 115, and the first conductive layer 113 between the gate hard mask patterns 119 are etched by an etch process using the gate hard mask patterns 119 as an etch mask.

Consequently, the dummy gate lines DL are formed in parallel to the isolation layers 103 (see FIG. 4a) and the fourth active regions 101c in the monitoring region of the semiconductor substrate 101. The gate lines DSL, SSL, and WL are formed to cross the isolation layers 103 and the first active regions 100 in the memory array region of the semiconductor substrate 101.

The gate lines DSL, SSL, and WL are formed on the semiconductor substrate 101 in the memory array region. The gate lines include the first gate lines DSL may be spaced from one another at a first interval, where an interval denotes a width or spacing. The first gate lines SSL may also be spaced from one another at the first interval. The second gate lines WL may be spaced from one another at second intervals narrower than the first interval. The dummy gate lines DL are formed on the semiconductor substrate 101 in the monitoring region.

Furthermore, in the process of forming the dummy gate lines DL and the gate lines DSL, SSL, and WL, at least three active regions (for example, comprised of the second and the third active regions 101a and 101b) or at least four isolation layers 103 may be formed adjacent to the monitoring region between the dummy gate lines DL. The at least three active regions and at least four isolation layers may be exposed.

Next, impurities are implanted into the active regions 100, 101a and 101b by using the dummy gate lines DL and the gate lines DSL, SSL, and WL as an impurity implantation mask. Consequently, first junctions 107D are formed between the first gate lines DSL and/or SSL, and second junctions 107C are formed between the second gate lines WL. Furthermore, at least three monitoring junctions M1 and M2 are formed between the dummy gate lines DL.

The monitoring junctions M1 and M2 are formed within the active regions 101a and 101b which are fully opened between the dummy gate lines DL. The monitoring junctions M1 and M2 are coupled without being broken within the active regions 101a and 101b.

The junctions 107D and 107C formed in the memory array region are formed in a part of the first active regions 100 opened between the gate lines DSL, WL, and SSL which are formed to cross the isolation layers 103 and the first active region 100. Accordingly, the junctions 107D and 107C formed in the memory array region are spaced from each other without being coupled within the first active region 100. Consequently, it is difficult to directly analyze the electrical characteristics of the junctions 107D and 107C formed in the first active region 100.

In this disclosure, however, since the monitoring junctions M1 and M2 are coupled within the active regions 101a and 101b, the electrical characteristic of each of the monitoring junctions M1 and M2 can be easily measured through the metal pads 151a and 151b. The metal pads 151a and 151b may be formed on both ends of each of the monitoring junctions M1 and M2.

Referring to FIGS. 3 and 4C. FIG. 4C depicts spacers 121 that may be formed on sidewalls of the gate lines DSL, WL, and SSL and the dummy gate lines DL. The spacers 121 may be formed by forming a spacer layer on a surface of the gate lines DSL, WL, and SSL and the dummy gate lines DL of the semiconductor substrate 101 and etching the spacer layer by an etch process, such as an etch-back process, so that the semiconductor substrate 101 is exposed.

In the memory array region, a space between the second gate lines WL which may be narrower than a space between the first gate lines DSL and/or SSL may be filled with the spacers 121, so that the second junctions 107C are covered by the spacers 121. Furthermore, since the space between the first gate lines DSL and/or SSL is relatively wide, the width of this space may not be completely filled with the spacers 121. Because the space between the first gate lines may not be completely filled, the first junctions 107D may be exposed between the spacers 121.

Furthermore, at least one monitoring junction M2 is covered by any one of the spacers 121. In this disclosure, since at least 3 active regions of 101a and 101b are exposed between the dummy gate lines DL, at least one monitoring junction M1 may be exposed between the spacers 121 formed on the sidewalls of the dummy gate lines DL. The monitoring junction M2, that resides on both sides of the first monitoring junction M1, may be exposed between the spacers 121 may be covered by any one of the spacers 121.

Accordingly, the second monitoring junction M2 covered by any one of the spacers 121 is protected from the etch process of the spacer layer, and thus electrical characteristics of the second junction 107C may be incorporated into the second monitoring junction M2. In other words, the second monitoring junction M2 may monitor the electrical characteristics of the second junction 107C. Furthermore, electrical characteristics of the first junction 107D of the memory array region exposed between the spacers 121 may be incorporated into the first monitoring junction M1 exposed between the spacers 121. In other words, first monitoring junction M1 may monitor the electrical characteristics of the first junction 107D.

In order to protect the second monitoring regions M2 and expose the first monitoring junction M1 through the spacers 121, a width W (see FIG. 4C) of the spacer 121 may be substantially the same as the sum of the width of the monitoring junction M1 or M2 and the width of the isolation layer 103.

Next, the first and the second contact plugs CT1 and CT2, and the first and the second metal pads 151a and 151b are formed as shown in FIG. 3.

In the process of forming the spacers, at least one of the monitoring junctions is protected by the spacers. Since the monitoring junction is protected by the spacers as described above, the accuracy of analysis into the cell junctions protected by the spacers in the memory array region can be increased.

What is claimed is:

1. A semiconductor device, comprising:
isolation layers arranged in a memory array region and a monitoring region, wherein the isolation layers are positioned in parallel;
gate lines arranged to cross the isolation layers in the memory array region, wherein the gate lines are formed in the memory array region;
dummy gate lines arranged in a substantially same direction as the isolation layers in the monitoring region, wherein the dummy gate lines are formed in the monitoring region;
monitoring junctions arranged between the dummy gate lines and in a substantially same direction of the dummy gate lines, wherein the monitoring junctions are arranged in the monitoring region; and
spacers arranged on sidewalls of each of the gate lines and the dummy gate lines, wherein at least one of the monitoring junctions is covered by any one of the spacers.

2. The semiconductor device of claim 1, wherein:
the gate lines include first gate lines spaced from one another at first interval and second gate lines spaced from one another at second interval narrower than the first interval;
the semiconductor device further comprises junctions arranged between the gate lines, wherein the junctions are arranged in the memory array region; and
the junctions include first junctions arranged between the first gate lines and second junctions arranged between the second gate lines.

3. The semiconductor device of claim 2, wherein:
the first gate lines comprise source select lines or drain select lines of a flash memory device; and
the second gate lines comprise word lines of the flash memory device.

4. The semiconductor device of claim 2, wherein:
the first junctions are exposed between the spacers; and
the second junctions are covered by the spacers.

5. The semiconductor device of claim 1, wherein the monitoring junctions comprise:
a first monitoring junction exposed between the spacers; and
a second monitoring junction covered by the any one of the spacers.

6. The semiconductor device of claim 5, further comprising:
first contact plugs formed on both ends of the first monitoring junction and coupled to the first monitoring junction; and
first metal pads formed on the first contact plugs, and coupled to the first contact plugs.

7. The semiconductor device of claim 5, further comprising:
second contact plugs formed on both ends of the second monitoring junctions and coupled to the second monitoring junctions; and
second metal pads formed on the second contact plugs and coupled to the second contact plugs.

8. The semiconductor device of claim 2, wherein the monitoring junctions have a substantially same width as junctions arranged between the gate lines.

9. The semiconductor device of claim 1, wherein a width of at least one of the spacers is identical with a sum of a width of the isolation layer and a width of the monitoring junction.

10. A method of manufacturing a semiconductor device, comprising:
forming isolation layers, in a memory array region and a monitoring region, wherein the isolation layers are positioned in parallel;
forming gate lines crossing the isolation layers in the memory array region and dummy gate lines arranged in a direction of the isolation layers in the monitoring region;
forming monitoring junctions arranged between the dummy gate lines and in a substantially same direction as the dummy gate lines; and
forming spacers on sidewalls of each of the gate lines and the dummy gate lines, wherein at least one of the monitoring junctions is covered by any one of the spacers.

11. The method of claim 10, wherein:
forming the gate lines includes forming first gate lines spaced from one another at a first interval and second gate lines spaced from one another at a second interval narrower than the first interval; and
further comprising forming junctions including first junctions between the first gate lines and second junctions between the second gate lines.

12. The method of claim 11, wherein forming the spacers is performed to expose the first junctions between the spacers and to cover the second junctions by the spacers.

13. The method of claim 10, wherein forming the gate lines and the dummy gate lines is performed to expose at least four of the isolation layers between the dummy gate lines.

14. The method of claim 10, wherein forming the gate lines and the dummy gate lines is performed to expose at least three of the monitoring junctions between the dummy gate lines.

15. The method of claim 10, wherein forming the spacers is performed to expose at least one of the monitoring junctions between the spacers adjacent to each other.

16. The method of claim 15, further comprising:
forming first contact plugs coupled to both ends of at least of the monitoring junctions exposed between the spacers adjacent to each other; and
forming first metal pads coupled to the first contact plugs and on the first contact plugs.

17. The method of claim 10, further comprising:
forming second contact plugs coupled to both ends of at least one of the monitoring junctions covered by the any one of the spacers; and
forming second metal pads coupled to the second contact plugs and on the second contact plugs.

18. The method of claim 10, wherein the monitoring junctions have a substantially same width as junctions arranged between the gate lines.

19. The method of claim 10, wherein a width of at least one the spacers is identical with a sum of a width of the isolation layer and a width of the monitoring junction.
